(19) United States
(12) Patent Application Publication
(10) Pub. No.: US 2012/0161753 A1
(43) Pub. Date: Jun. 28, 2012

(54) ELECTRIC POWER MEASURING DEVICE

(76) Inventor: Seiji KUMAZAWA, Osaka (JP)

(21) Appl. No.: 13/237,997

(22) Filed: Sep. 21, 2011

(30) Foreign Application Priority Data
Dec. 27, 2010 (JP) 2010-289662

(51) Int. Cl. G01R 1/04

(52) U.S. Cl. 324/156

(57) ABSTRACT

An electric power measuring device (100) includes: a case (104) that includes a first opening (122); a cover (112) that covers the first opening (122); a printed board (128) that includes an electric power measuring portion; and a connector (114) that includes a plug portion (101) and a socket portion (102). In the electric power measuring device, the printed board (128) is arranged within the case (104), part of the connector (114) is arranged within the case (104), the plug portion (101) and the socket portion (102) are integrally coupled to each other, the connector (114) is fixed to a side opposite the first opening of the case (104), and the connector (114) is electrically connected to the printed board (128).

This nonprovisional application claims priority under 35 U.S.C. §119 (a) on Patent Application No. 2010-289662 filed in Japan on Dec. 27, 2010, the entire contents of which are hereby incorporated by reference.

### BACKGROUND OF THE INVENTION

1. Field of the Invention

The present invention relates to an electric power measuring device that measures the power consumption of an electronic device.

2. Description of the Related Art

In recent years, consideration given to reduction of burden on the natural environment has caused people to increasingly focus on energy saving; not only in companies but also in common households, it is increasingly required to constantly check the power consumption of an electronic device that is used. In order to meet the requirement, devices (such as air conditioners) that have the function of measuring and displaying the power consumption have recently been widely available.

The device described above naturally can measure its power consumption but cannot measure the power consumption of other devices. Therefore, such a device cannot meet the requirement for finding the power consumption of all electronic devices that are used.

Hence, in order to measure the power consumption of a device that does not have the function of measuring the power consumption, electric power measuring devices are proposed. FIGS. 5 and 6 show a conventional electric power measuring device (e.g. JP-A-H8-184616).

FIG. 5 shows a perspective view of the electric power measuring device 10. The electric power measuring device 10 includes: a case 14; a plug portion 11 that is inserted into a socket (not shown) of a commercial power supply; a socket portion 12 to which a power plug 13 of an electrical device (not shown) whose power consumption is to be measured is connected; a display portion 15 that displays the power consumption and the like of the electrical device; and an electrical power measuring circuit 16 that is placed into the device. The size of the electric power measuring device 10 is about 160 mm×100 mm×70 mm.

FIG. 6 is a block diagram of the electric power measuring device 10. In FIG. 6, the same components as in FIG. 5 are identified with common symbols; the plug portion 11 and the socket portion 12 are connected to each other through connection wires 17.

However, as shown in FIG. 5, in the conventional electric power measuring device 10, the plug portion 11 and the socket portion 12 are respectively arranged near edges of opposite corners. In other words, the plug portion 11 and the socket portion 12 are supported by different portions of the case 14. Specifically, the socket portion 12 is supported by the front surface of the case 14, and the plug portion 11 is supported by the back surface that is opposite the front surface.

When a failure occurs in a final finish inspection or the like in the manufacturing process of the electric power measuring device 10, it is necessary to open the electric power measuring device 10 so as to perform an inspection and a readjustment on the electrical power measuring circuit 16 therewithin. However, in the structure described above, the following problems are encountered.

In order to open the electric power measuring device 10, it is necessary to separate, from the case 14, at least one of the six surfaces that form the case 14. If the front surface that supports the socket portion 12 or the back surface that supports the plug portion 11 is separated from the case 14, in order to perform an inspection or the like on the inside, it is required to extend more than necessary the connection wires 17 (see FIG. 6) through which the plug portion 11 and the socket portion 12 are connected. In this case, wastefully long wires are used within the electric power measuring device 10, and this is not preferable in terms of safety.

If the surface that is separated from the case 14 is at least one of the four side surfaces between the front surface and the back surface, due to the size mentioned above (160 mm×100 mm×70 mm), it is difficult to form an opening enough for the operation. Therefore, it is difficult to easily perform an inspection or the like on the inside.

### SUMMARY OF THE INVENTION

An object of the present invention is to provide an electric power measuring device on which operations such as an inspection and a readjustment in its manufacturing process are easily performed and in which the device is easily opened.

According to the present invention, there is provided an electric power measuring device including: a case that includes a first opening; a cover that covers the first opening; a printed board that includes an electric power measuring portion; and a connector that includes a plug portion and a socket portion. The printed board is arranged within the case. Part of the connector is arranged within the case. The plug portion and the socket portion are formed integrally with each other. The connector is fixed to a side opposite the first opening of the case. The connector is electrically connected to the printed board.

The case includes a second opening in the side opposite the first opening. A recess portion is provided around the second opening. The socket portion is covered with a resin portion. The resin portion is formed to sandwich the recess portion. The resin portion may include a socket mouth portion so that the socket mouth portion is connected to a plug of another device.

The cover includes a hole portion through which the plug portion protrudes, and the hole portion does not make contact with the plug portion.

A support portion is provided within the case, and the support portion extends to the first opening and supports the printed board. The printed board may include an electronic component on a surface supported by the support portion.

The plug portion is a plurality of conductive members, and the socket portion is a plurality of conductive members. A resistor may be inserted between a first conductive member of the plug portion and a first conductive member of the socket portion. Both ends of the resistor are electrically connected to the printed board.

In the electric power measuring device of the present invention, the position of the connectors (the plug portion and the socket portion) and the position of the printed board do not change. Thus, in a final finish inspection and the like of the electric power measuring device, an inspection, a readjustment and the like on the internal circuit are easily performed, and the workability thereof is enhanced.

### BRIEF DESCRIPTION OF THE DRAWINGS

FIG. 1 is a block diagram of an electric power measuring device according to a first embodiment of the present invention;

FIG. 2 is an assembly perspective view of the electric power measuring device according to the first embodiment when seen from above;

FIG. 3 is an assembly perspective view of the electric power measuring device according to the first embodiment when seen from below;

FIG. 4 is a partial enlarged perspective view of the electric power measuring device according to a second embodiment of the present invention;

FIG. 5 is a perspective view showing a conventional electric power measuring device; and

FIG. 6 is a block diagram showing the conventional electric power measuring device.

### DETAILED DESCRIPTION OF THE PREFERRED EMBODIMENTS

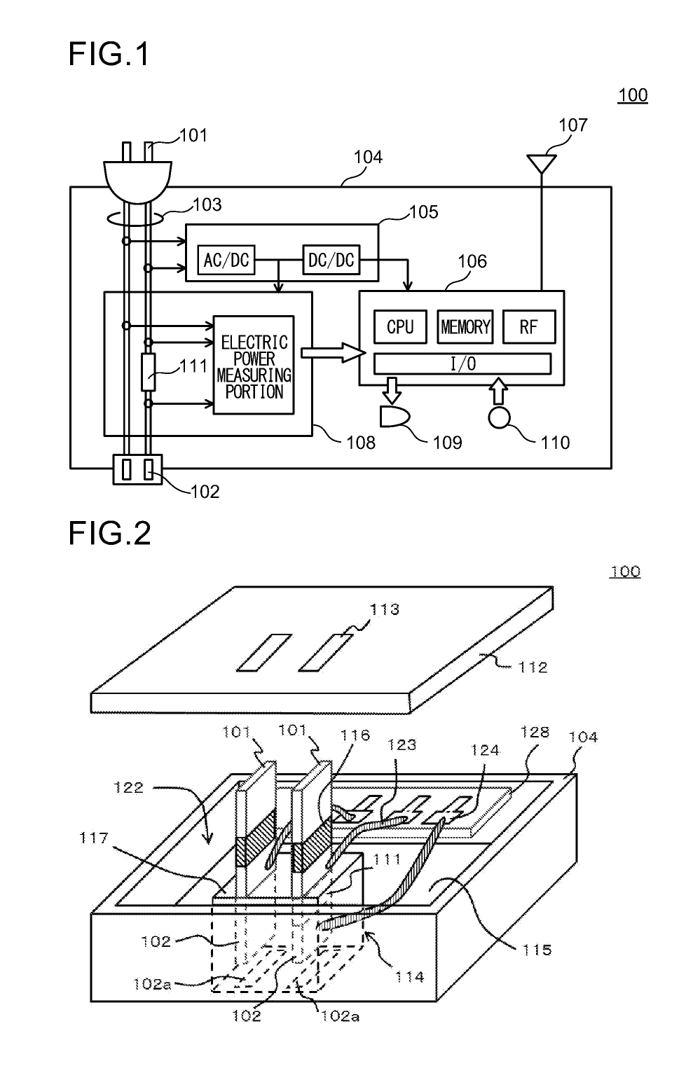

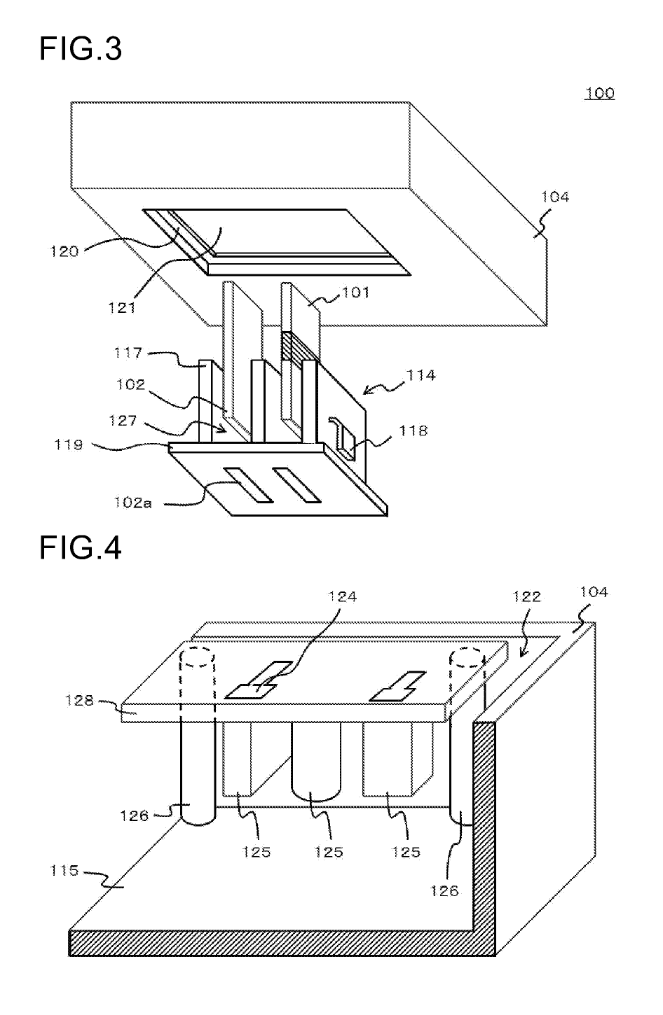

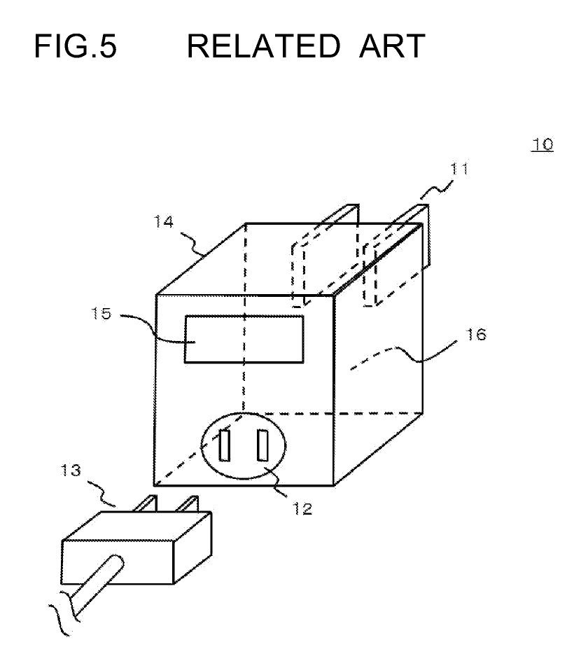

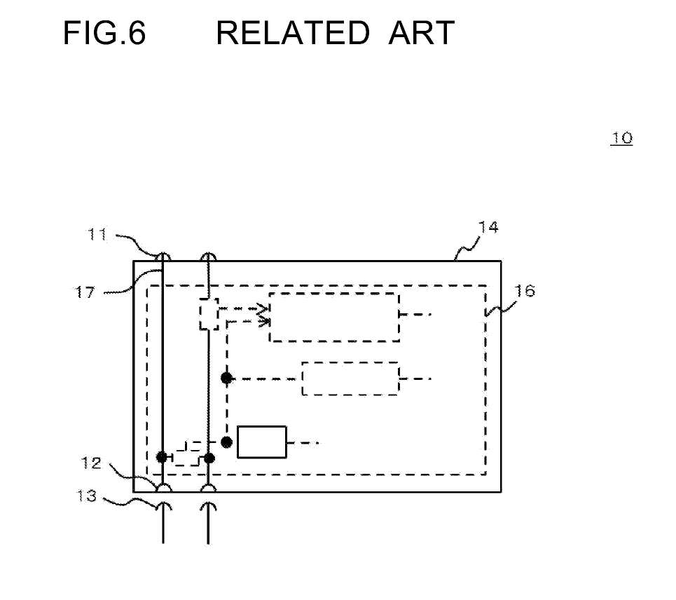

A first embodiment of the present invention will be described below with reference to FIGS. 1 to 3. FIG. 1 is a block diagram of an electric power measuring device according to the first embodiment; FIGS. 2 and 3 show assembly perspective views.

The function of the electric power measuring device will first be described with reference to FIG. 1. The electric power measuring device 100 includes a plug portion 101 and a socket portion 102. An alternating-current voltage from a commercial power supply (not shown) is fed to the plug portion 101. The socket portion 102 is connected to the plug portion 101; a power plug (not shown) of an electrical device whose electric power is to be measured is connected to the socket portion 102.

The alternating-current voltage fed to the plug portion 101 is supplied through conductive portions 103 to a power supply portion 105. The conductive portion 103 is a coupling portion through which the plug portion 101 and the socket portion 102 are coupled to each other. The power supply portion 105 generates an operation voltage for a circuit within the electric power measuring device 100.

The power supply portion 105 includes an AC/DC conversion portion and a DC/DC conversion portion. The AC/DC conversion portion generates, from the alternating-current voltage supplied from the plug portion 101, a direct-current voltage that is an operation voltage for a sensor portion 108. The DC/DC conversion portion generates, from the direct-current voltage generated by the AC/DC conversion portion, a direct-current voltage that is an operation voltage for a communication portion 106.

The sensor portion 108 for the measurement of an electric power is connected to the conductive portions 103. The sensor portion 108 includes an electric power measuring portion; the electric power measuring portion measures the power consumption of the electrical device (such as a household appliance or an office device) connected to the socket portion 102.

The electric power measurement will be further specifically described. A voltage across both terminals of the socket portion 102 and a voltage of a shunt resistor 111 inserted into one of the two conductive portions 103 are used, and a current consumption and the voltage across both terminals of the socket portion 102 are multiplied, and thus a consumption power is measured.

Power consumption measurement information that is measured by the sensor portion 108 is transmitted to the communication portion 106. The communication portion 106 includes a CPU (central processing unit), a memory portion, a RF portion and an I/O portion. The CPU calculates the power consumption from the transmitted power consumption measurement information. The memory portion temporarily stores the calculated value of the power consumption. The RF portion wirelessly transmits the calculated value of the power consumption to an external server. The I/O portion is an interface with the outside of the device. An antenna 107 for the wireless transmission is connected to the communication portion 106.

In the present embodiment, the calculated value of the power consumption is wirelessly transmitted to the external server. However, the calculated value of the power consumption may be transmitted with a cable (such as a LAN cable) to the external server. The calculated value of the power consumption may not be transmitted to the external server; the calculated value of the power consumption may be stored in the memory portion within the communication portion 106 or in the other storage portion (not shown) within the electric power measuring device 100, and the calculated value of the power consumption can be read and displayed as appropriate. The transmission of the calculated value of the power consumption without or with a cable and the storage of the calculated value of the power consumption within the device may be combined together.

The electric power measuring device 100 also includes an operation state display LED 109 and an externally manually operated switch 110. The setting (for example, flashing) of the LED 109 and the change of the operation setting with the switch 110 are controlled by the CPU within the communication portion 106.

The structure of the electric power measuring device according to the first embodiment will now be described with reference to FIGS. 2 and 3. The components shown in FIG. 1 will be identified with the same symbols and described.

FIG. 2 is a perspective view of the electric power measuring device 100 when seen from above. The electric power measuring device 100 includes a case 104, a printed board 128 and a connector 114 in which the plug portion 101 and the socket portion 102 are formed integrally. The case 104 has an opening 122 in one surface. The printed board 128 is arranged within the case 104 and is supported. Part of the connector 114 is arranged within the case 104.

On the printed board 128, the power supply portion 105, the communication portion 106, the antenna 107, the sensor portion 108, the LED 109 and the switch 110 (see FIG. 1) are mounted. In FIG. 2, the details of the printed board 128 are omitted.

The connector 114 is electrically connected to conductive members 124 on the printed board 128 through connection wires 123. The plug portion 101 may be connected to the conductive members 124; the socket portion 102 may be connected to the conductive members 124. The conductive members 124 are part of a circuit of the power supply portion 105, the sensor portion 108 (see FIG. 1) or the like.

Although, in FIG. 2, the conductive members 124 are arranged on the upper surface of the printed board 128, if necessary in particular, the conductive members 124 may be arranged on the lower surface of the printed board 128.

The printed board 128 and part of the connector 114 are placed within the case 104, and thereafter a cover 112 covers the opening 122 of the case 104, and the cover 112 is fitted to the case 104.

The structure of the connector 114 will now be described in detail. The connector 114 includes the plug portion 101 and the socket portion 102 coupled to the plug portion 101. The plug portion 101 is a pair of metal members; the socket portion 102 is a pair of metal members. The plug portion 101 and the socket portion 102 are coupled to each other through the conductive portions 103 (see FIG. 1).

In FIG. 2, the conductive portions 103 themselves are omitted. The conductive portions 103 may be part of the plug portion 101 or part of the socket portion 102; alternatively, the conductive portions 103 may be separated from the plug portion 101 and the socket portion 102.

Part of the plug portion 101 is covered with an insulator 116 so that tracking is prevented. The part of the plug portion 101 covered with the insulator 116 is thinner by the thickness of the insulator 116, and thus, when the part is covered with the insulator 116, the part is flush with part of the plug portion 101 that is not covered with the insulator 116.

The socket portion 102 is covered with a resin portion 117, and extends close to a socket mouth portion 102a provided in the bottom portion of the resin portion 117. When the power plug (not shown) of the electrical device is inserted into the socket mouth portion 102a, the socket portion 102 makes contact with the power plug.

A shunt resistor 111 is inserted between a first metal member of the plug portion 101 and a first metal member of the socket portion 102. Although not illustrated in detail, the shunt resistor 111 is coupled to, for example, the first metal member of the plug portion 101 and the first metal member of the socket portion 102 with a rivet or the like. The shunt resistor 111 may be welded with solder or the like. Hence, the first metal member of the plug portion 101 and the first metal member of the socket portion 102 are integrally formed through the shunt resistor 111.

A second metal member of the plug portion 101 and a second metal member of the socket portion 102 are integrally formed. The second metal member of the plug portion 101 and the second metal member of the socket portion 102 may be formed with the same metal member. In this case, a portion including one end of the same metal member is the plug portion 101, and a portion including the other end of the same metal member is the socket portion 102.

As described above, in the connector 114, the plug portion 101 and the socket portion 102 are formed integrally.

With reference to FIG. 3, the connector 114 will now be described in further detail, and the structure of support of the connector 114 by the case 104 will be described in detail. FIG. 3 is a perspective view of the electric power measuring device 100 when seen from below. The resin portion 117 of the connector 114 includes: a slit portion 127 that previously incorporates the plug portion 101 and the socket portion 102; a locking portion 118 and a frame portion 119. On the other hand, in the bottom surface of the case 104, an opening 121 and a recess portion 120 provided around the opening 121 are provided.

The resin portion 117 may make contact with the socket portion 102. Part of the socket portion 102 does not need to be covered with the resin portion 117. In FIG. 3, the insulator 116 (see FIG. 2) is not shown.

The connector 114 is introduced into the opening 121 from below the case 104, and thereafter the recess portion 120 of the case 104 is sandwiched between the locking portion 118 and the frame portion 119. In this way, the connector 114 is fixed to the case 104 (the connector 114 is supported by the case 104).

The thickness dimension of the frame portion 119 of the resin portion 117 is equal to the dimension of recess of the recess portion 120 of the case 104. The connector 114 is fixed to the case 104, and thereafter the bottom surface of the connector 114 becomes flush with the bottom surface of the case 104.

The connector 114 is fixed to the case 104, and thereafter the connector 114 and the printed board 128 are connected (see FIG. 2).

The fitting of the cover 112 to the case 104 will be described with reference to FIG. 2. The cover 112 includes a hole portion 113. When the cover 112 is fitted to the case 104, the plug portion 101 penetrates the hole portion 113, and protrudes to the outside of the cover 112. The hole portion 113 does not make contact with the plug portion 101. In other words, the cover 112 does not support the connector 114 including the plug portion 101.

Hence, in the electric power measuring device 100 of the present embodiment, when the cover 112 is removed from the case 104, the positions of the printed board 128, the plug portion 101, the socket portion 102 do not change, and thus operations such as an inspection and a readjustment are easily performed. Moreover, since the cover 112 does not make contact with the plug portion 101, the cover 112 is easily removed, and the workability of the inspection and the readjustment on the inner circuit is enhanced.

A second embodiment of the present invention will now be described with reference to FIG. 4. FIG. 4 is an enlarged perspective view showing a relationship between the printed board 128 and the case 104 in FIG. 2. The same components as in FIG. 2 are identified with the same symbols.

In the present embodiment, as shown in FIG. 4, support portions 126 are provided within the case 104, and end portions of the support portions 126 extend close to the opening surface of the opening 122 of the case 104 and support the printed board 128. In FIG. 4, the support portions 126 support a plurality of portions of the printed board 128.

In the structure described above, the position of the printed board 128 in the height direction is close to the opening surface of the opening 122, and thus operations such as the inspection, the readjustment and the like on the internal circuit are easily performed after the cover 112 (see FIG. 2) is removed from the case 104.

In the above structure, there is a space between the lower surface of the printed board 128 and a bottom surface 115 of the case 104. This space produces the following secondary effects. Erect tall components are used as the power supply portion 105, the communication portion 106, the LED 109 and the like (see FIG. 1). In the present embodiment, the erect components 125 can be arranged on the lower surface of the printed board 128. It is therefore possible to effectively use the space within the case 104.

Hence, in the electric power measuring device 100 of the present embodiment, when the cover 112 is removed from the case 104, the position of the printed board 128 is close to the opening surface of the opening 122, and thus the operations such as the inspection, the readjustment and the like on the internal circuit are easily performed. It is also possible to effectively use the space within the case 104.

The support portions 126 may have another shape. The support portion 126 may support one portion of the printed board 128. Part of the resin portion 117 (see FIGS. 2 and 3) may support part of the printed board 128.

Although, in the first and second embodiments, the light emission portion of the LED 109 can be recognized from the outside of the case 104, and the switch 110 can be operated from the outside of the case 104, the detailed description thereof is omitted.

The plug portion 101 and the socket portion 102 of other types may be used. In this case, the hole portion 113 and the socket mouth hole 102a are also changed.

Conductive members other than the metal members may be used as the plug portion 101 and the socket portion 102.

The antenna 107 (see FIG. 1) of the electric power measuring device 100 may receive control signals; the electric power measuring device 100 may be controlled based on the received control signals.

The electric power measuring device of the present invention can be widely utilized as electric power measuring devices for household appliances, industrial devices and the like that do not have the function of electric power measurement.

What is claimed is:

1. An electric power measuring device comprising:
a case that includes a first opening;
a cover that covers the first opening;
a printed board that includes an electric power measuring portion; and
a connector that includes a plug portion and a socket portion,
wherein the printed board is arranged within the case,
part of the connector is arranged within the case,
the plug portion and the socket portion are formed integrally with each other,
the connector is fixed to a side opposite the first opening of the case, and
the connector is electrically connected to the printed board.

2. The electric power measuring device of claim 1,
wherein the case includes a second opening in the side opposite the first opening,
a recess portion is provided around the second opening,
the socket portion is covered with a resin portion, and
the resin portion is formed to sandwich the recess portion.

3. The electric power measuring device of claim 2,
wherein the resin portion includes a socket mouth portion so that the socket mouth portion is connected to a plug of another device.

4. The electric power measuring device of claim 1,
wherein the cover includes a hole portion through which the plug portion protrudes, and
the hole portion does not make contact with the plug portion.

5. The electric power measuring device of claim 1,
wherein a support portion is provided within the case, and
the support portion extends to the first opening and supports the printed board.

6. The electric power measuring device of claim 5,
wherein the printed board includes an electronic component on a surface supported by the support portion.

7. The electric power measuring device of claim 1,
wherein the plug portion is a plurality of conductive members,
the socket portion is a plurality of conductive members,
a resistor is inserted between a first conductive member of the plug portion and a first conductive member of the socket portion, and
both ends of the resistor are electrically connected to the printed board.
